(19) United States
(12) Patent Application Publication
(10) Pub. No.: US 2025/0003064 A1
(43) Pub. Date: Jan. 2, 2025

(54) Particle Coating Apparatus And Method Of Coating Particle

(71) Applicant: SEIKO EPSON CORPORATION, Tokyo (JP)

(72) Inventors: Teruaki NANBA, Chino (JP); Shinichi UEDA, Chino (JP); Ryujiro SAIBA, Matsumoto (JP); Kunio NISHIZAWA, Suwa (JP); Hiroyuki CHINO, Shiojiri (JP); Yoshihiro ITO, Chino (JP)

(21) Appl. No.: 18/757,742

(22) Filed: Jun. 28, 2024

(30) Foreign Application Priority Data
Jun. 29, 2023 (JP) 2023-106815

(51) Int. Cl. C23C 16/44; C23C 16/02; C23C 16/455; C23C 16/458; C23C 16/505

(52) U.S. Cl. CPC C23C 16/4417; C23C 16/0218; C23C 16/4412; C23C 16/45534; C23C 16/45536; C23C 16/4583; C23C 16/505

(57) ABSTRACT

A particle coating apparatus configured to form a coating film on a surface of a particle of a treatment target powder using an atomic layer deposition method, includes a processing chamber including a chamber, and an opening/closing unit configured to open and close the chamber, a material gas supply unit configured to supply a material gas into the processing chamber, an oxidizing agent supply unit configured to supply an oxidizing agent into the processing chamber, a processing chamber exhaust unit configured to exhaust the processing chamber, a plurality of trays which is configured to be carried into the processing chamber through the opening/closing unit, and which is configured to hold a powder layer formed of the treatment target powder laid in a layer, and a placement part which is disposed in the processing chamber, and on which the plurality of trays is detachably placed.

The present application is based on, and claims priority from JP Application Serial Number 2023-106815, filed Jun. 29, 2023, the disclosure of which is hereby incorporated by reference herein in its entirety.

### BACKGROUND

### 1. Technical Field

The present disclosure relates to a particle coating apparatus and a method of coating particles.

### 2. Related Art

In the magnetic powder used for an inductor or the like, it is necessary to perform an insulating treatment on surfaces of particles to suppress an eddy current flowing between the particles or insulate the particles from each other. Therefore, a method of forming an insulating film on the surfaces of the particles of magnetic powder using various film formation methods has been studied.

For example, JP-A-2021-085050 discloses a particle coating apparatus that forms an insulating film on a surface of a soft magnetic metal particle by an atomic layer deposition (ALD) method, which is one type of a chemical vapor deposition method. According to the atomic layer deposition method, an insulating film thin and uniform in film thickness can be formed.

JP-A-2021-085050 is an example of the related art.

In the particle coating apparatus described in JP-A-2021-085050, soft magnetic metal particles are put into a tray to form a coating film, but in order to form a film with a uniform film thickness, it is necessary to limit the amount of soft magnetic metal particles put into the tray. Therefore, the particle coating apparatus described in JP-A-2021-085050 has a problem that the production efficiency of the coated particles cannot be sufficiently increased. In addition, JP-A-2021-085050 does not disclose how soft magnetic metal particles are put into a tray. In general, an operation of placing soft magnetic metal particles in a tray disposed in a vacuum chamber, and spreading the soft magnetic metal particles in the tray has a high degree of difficulty and is low in work efficiency.

### SUMMARY

A particle coating apparatus according to an application example of the present disclosure is a particle coating apparatus configured to form a coating film on a surface of a particle of a treatment target powder using an atomic layer deposition method, including:
a processing chamber including a chamber, and an opening/closing unit configured to open and close the chamber;
a material gas supply unit configured to supply a material gas into the processing chamber;
an oxidizing agent supply unit configured to supply an oxidizing agent into the processing chamber;
a processing chamber exhaust unit configured to exhaust the processing chamber;
a plurality of trays which is configured to be carried into the processing chamber through the opening/closing unit, and which is configured to hold a powder layer formed of the treatment target powder laid in a layer; and
a placement part which is disposed in the processing chamber, and on which the plurality of trays is detachably placed.

A method of coating a particle according to an application example of the present disclosure is a method of coating a particle for forming a coating film on a surface of a particle of a treatment target powder using an atomic layer deposition method, including:
carrying a plurality of trays holding a powder layer formed by laying the treatment target powder in a layer into a processing chamber through an opening/closing unit;
forming the coating film in the powder layer using the atomic layer deposition method in the processing chamber after the opening/closing unit is closed; and
opening the opening/closing unit to carry the plurality of trays holding the powder layer coated with the coating film out from the processing chamber.

### BRIEF DESCRIPTION OF THE DRAWINGS

FIG. 1 is a cross-sectional view illustrating a powder layer forming unit provided to a particle coating apparatus according to an embodiment.

FIG. 2 is a cross-sectional view illustrating a film forming unit provided to the particle coating apparatus according to the embodiment.

FIG. 3 is a cross-sectional view schematically showing an example of a coated particle manufactured by the particle coating apparatus shown in FIGS. 1 and 2.

FIG. 4 is a process chart showing a method of coating the particles according to the embodiment.

FIG. 5 is a diagram schematically showing a method of collecting the coated particles from a tray in a collection step.

FIG. 6 is a cross-sectional view illustrating a film forming unit provided to a particle coating apparatus according to a first modified example.

FIG. 7 is a perspective view illustrating a squeegee provided to a particle coating apparatus according to a second modified example.

FIG. 8 is a cross-sectional view illustrating a film forming unit provided to a particle coating apparatus according to a third modified example.

FIG. 9 is a cross-sectional view illustrating a tray provided to a particle coating apparatus according to a fourth modified example.

### DESCRIPTION OF EMBODIMENTS

Hereinafter, an exemplary embodiment of a particle coating apparatus and a method of coating particles according to the present disclosure will be described in detail based on the accompanying drawings.

### 1. Particle Coating Apparatus

First, the particle coating apparatus according to the embodiment will be described.

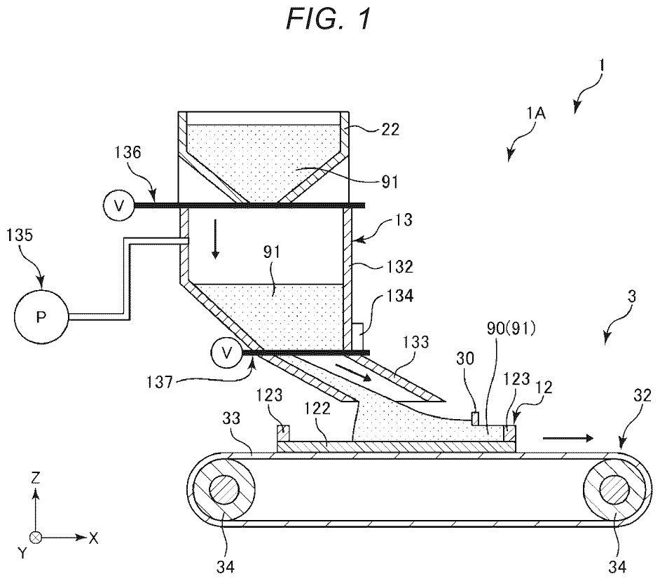

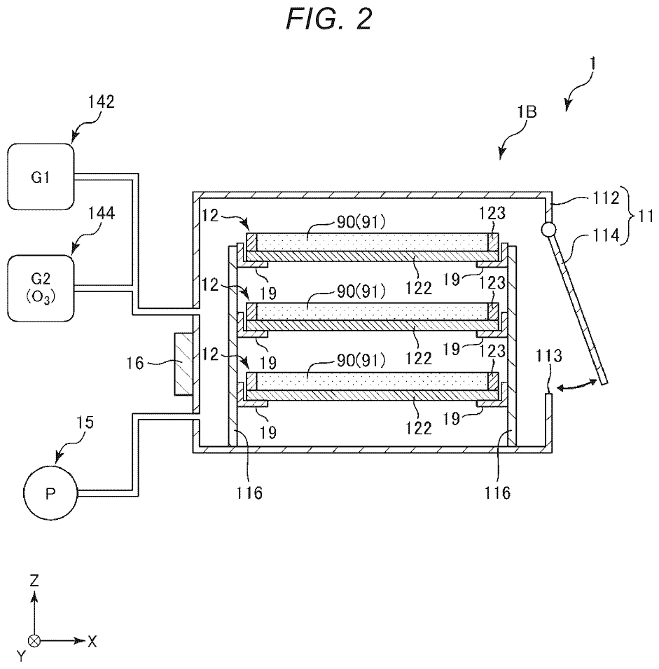

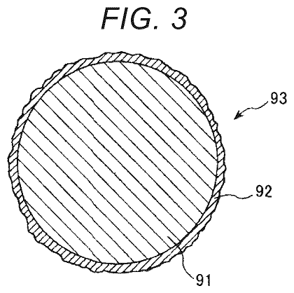

FIG. 1 is a cross-sectional view illustrating a powder layer forming unit 1A provided to a particle coating apparatus 1 according to the embodiment. FIG. 2 is a cross-sectional view illustrating a film forming unit 1B provided to the particle coating apparatus 1 according to the embodiment. FIG. 3 is a cross-sectional view schematically showing an example of a coated particle 93 manufactured by the particle coating apparatus 1 shown in FIGS. 1 and 2. In the drawings of the present application, for the sake of convenience of explanation, an X axis, a Y axis, and a Z axis are set as three axes orthogonal to each other, and each axis is indicated by an arrow. The Z axis is a vertical axis, and the X-Y plane is a horizontal plane. The base end side of the arrow is referred to as the minus side of each axis, and the tip end side is referred to as the plus side of each axis.

The particle coating apparatus 1 shown in FIGS. 1 and 2 is an apparatus that forms a coating film 92 shown in FIG. 3 on a surface of a particle 91 by the atomic layer deposition (ALD) method. In the following description, the aggregate of the particles 91 is referred to as “treatment target powder”.

The particle coating apparatus 1 according to the present embodiment is configured with the powder layer forming unit 1A shown in FIG. 1 and the film forming unit 1B shown in FIG. 2.

### 1.1. Powder Layer Forming Unit

The powder layer forming unit 1A illustrated in FIG. 1 includes a powder supply unit 13 and a powder layer forming unit 3.

The powder supply unit 13 includes an anterior chamber 132, a supply nozzle 133, an anterior chamber heating unit 134, an anterior chamber exhaust unit 135, an upper gate valve 136, and a lower gate valve 137.

The anterior chamber 132 is a container having rigidity and airtightness, and accommodates the treatment target powder therein. The anterior chamber 132 maintains a reduced pressure state by exhausting the inside. Examples of the constituent material of the anterior chamber 132 includes a glass material such as quartz glass, a ceramic material such as alumina, and a metal material such as stainless steel, aluminum, and titanium.

The supply nozzle 133 is a flow channel coupled to a lower end of the anterior chamber 132. The supply nozzle 133 supplies the treatment target powder housed in the anterior chamber 132 downward as a minute flow.

The anterior chamber heating unit 134 heats the anterior chamber 132. Examples of the anterior chamber heating unit 134 include a heater block, a film heater, a sheet heater, a sheathed heater, and an infrared radiation heater.

The anterior chamber exhaust unit 135 exhausts the anterior chamber 132. The anterior chamber exhaust unit 135 includes, for example, a vacuum pump, a pressure gauge, a pipe, and an opening/closing valve.

The anterior chamber 132 is supplied with the treatment target powder from a supply hopper 22. The supply hopper 22 is a portable container that contains treatment target powder.

The upper gate valve 136 is disposed at an upper end of the anterior chamber 132, and switches the supply of the treatment from the supply hopper 22 disposed above the anterior chamber 132 into the anterior chamber 132. By transferring the treatment target powder from the supply hopper 22 to the anterior chamber 132, the treatment target powder can temporarily be stored in an appropriate environment. The appropriate environment refers to an environment in which contact with the outside air is avoided and a predetermined temperature is maintained. In addition, the upper gate valve 136 may sufficiently have a blocking property such that the supply of the treatment target powder can be stopped when the upper gate valve 136 is closed, but preferably has airtightness. Accordingly, it is possible to avoid contact between the treatment target powder housed in the anterior chamber 132 and the outside air, and it is possible to prevent an influence of oxygen, moisture, or the like on the treatment target powder.

The lower gate valve 137 is disposed between the anterior chamber 132 and the supply nozzle 133, and has a function of switching supply when the treatment target powder supplied to the anterior chamber 132 is supplied downward through the supply nozzle 133. Accordingly, the supply amount of the treatment target powder can finely be adjusted. In addition, the lower gate valve 137 may sufficiently have a blocking property such that the supply of the treatment target powder can be stopped when the lower gate valve 137 is closed, but preferably has airtightness. Accordingly, it is possible to avoid contact between the treatment target powder housed in the anterior chamber 132 and the outside air, and it is possible to prevent an influence of oxygen, moisture, or the like on the treatment target powder.

The upper gate valve 136 and the lower gate valve 137 are manually or electrically operated.

The powder layer forming unit 3 includes a tray conveyance unit 32 and a squeegee 30. The tray conveyance unit 32 conveys the tray 12 so that the treatment target powder supplied from the powder supply unit 13 is deposited on the tray 12. As shown in FIG. 1, the tray 12 is a container including a bottom plate 122 and a frame body 123. The bottom plate 122 has a plate shape spreading along the X-Y plane, and the frame body 123 has an annular shape having a square outer shape and is disposed on the surface at the positive side of the Z axis of the bottom plate 122. The inner space defined by the bottom plate 122 and the frame body 123 accommodates the treatment target powder. The tray conveyance unit 32 includes a conveyor belt 33 and a conveyor roller 34. The conveyor belt 33 conveys the tray 12 placed thereon toward the X-axis positive side. The conveyor roller 34 drives the conveyor belt 33. The squeegee 30 is disposed above a space through which the tray 12 passes. The treatment target powder deposited on the tray 12 is leveled by the squeegee 30 when passing below the squeegee 30. Thus, a powder layer 90 in which the treatment target powder is laid in a layer along the X-Y plane is formed on the tray 12. The squeegee 30 has, for example, a plate shape that extends along the Y-Z plane and is elongated in the Y-axis direction.

Since the powder layer forming unit 3 as described above is disposed outside a processing chamber 11, the powder layer 90 can be formed without being restricted by space or workability. Therefore, it is possible to easily speed up the formation of the powder layer 90. The configuration of the powder layer forming unit 1A is not limited to the above. For example, the anterior chamber heating unit 134, the anterior chamber exhaust unit 135, the upper gate valve 136, the tray conveyance unit 32, and the like may be provided as necessary, and may be omitted. The entire powder layer forming unit 1A may be provided as necessary, and may be replaced with another device capable of forming the powder layer 90.

### 1.2. Film Forming Unit

The film forming unit 1B illustrated in FIG. 2 includes the processing chamber 11, the trays 12, placement parts 19, a material gas supply unit 142, an oxidizing agent supply unit 144, a processing chamber exhaust unit 15, and a processing chamber heating unit 16. In the film forming unit 1B, the treatment target powder (particles 91) is housed in the processing chamber 11, the inside of the processing chamber 11 is exhausted by the processing chamber exhaust unit 15, and then the material gas supply unit 142 and the oxidizing agent supply unit 144 introduce the material gas G1 and the oxidizing agent G2. The treatment target powder is heated by the processing chamber heating unit 16. The material gas G1 introduced into the processing chamber 11 is decomposed, and decomposition products are adsorbed on the surfaces of the particles 91 of the treatment target powder, whereby the coating film 92 shown in FIG. 3 is finally formed. Thus, the coated particles 93 shown in FIG. 3 are obtained. In the following description, aggregate of the coated particles 93 is also referred to as “treated powder”.

The processing chamber 11 is a container having rigidity and airtightness, and forms the coating film 92 on the surface of the particles 91 of the treatment target powder in a state where the treatment target powder is housed therein. The processing chamber 11 is maintained in a reduced pressure state by exhaust of the inside thereof. Examples of the constituent material of the processing chamber 11 include a glass material such as quartz glass, a ceramic material such as alumina, and a metal material such as stainless steel, aluminum, or titanium.

The processing chamber 11 illustrated in FIG. 2 includes a chamber 112 having an opening 113 and an opening/closing unit 114 as a door that opens and closes the opening 113. When closed, the opening/closing unit 114 airtightly closes the opening 113. On the other hand, when the opening/closing unit 114 is opened, the opening 113 is set in a state in which the tray 12 can pass through the opening 113. By providing such an opening/closing unit 114, it is possible to efficiently carry the tray 12 into or out of the processing chamber 11. In addition, the tray 12 can be carried in while holding the powder layer 90. Therefore, it is also useful from the viewpoint of efficiently forming the powder layer 90 outside the processing chamber 11. As a result, the production efficiency of the coated particles 93 can be increased.

In FIG. 2, the opening 113 is provided in a wall crossing the X axis of the processing chamber 11, but the opening 113 may be provided in a wall crossing the Y axis or a wall crossing the Z axis. Further, a plurality of openings 113 may be provided.

A plurality of the trays 12 is disposed in the processing chamber 11. The trays 12 each hold the treatment target powder in the form of the powder layer 90 in which the treatment target powder is laid in a layer. The holding means maintaining the relative positions of the particles 91 so as not to change, and specifically means that the powder layer 90 is left at rest. By arranging the plurality of trays 12, a large amount of treatment target powder can be supplied in one film forming step. Accordingly, the production efficiency of the coated particles 93 can be increased.

The size of the tray 12 is appropriately set according to the size of the processing chamber 11 and so on. As an example, the maximum length that can be taken along the X-Y plane is preferably 100 mm or more and 2000 mm or less, and more preferably 200 mm or more and 1000 mm or less. The constituent material of the tray 12 is not particularly limited, and examples thereof include a metal material, a resin material, a ceramic material, a glass material, and a carbon material. The constituent material of the tray 12 may be a composite material containing two or more of these.

The separation distance between the trays 12 is appropriately set in accordance with the size of the trays 12 or the like, and as an example, the minimum separation distance along the Z axis is preferably 10 mm or more, and more preferably 20 mm or more. This makes it easier for the material gas G1 and the oxidizing agent G2 to enter the gaps between the trays 12, and makes it easier to form the coating film 92 with a uniform film thickness. On the other hand, from the viewpoint of preventing the length of the processing chamber 11 in the Z-axis direction from being unnecessarily increased, the upper limit value of the minimum separation distance along the Z axis is preferably 1000 mm or less, and more preferably 500 mm or less.

The number of trays 12 housed in the processing chamber 11 is not particularly limited as long as it is plural, but is preferably three or more, and more preferably five or more and twenty or less, from the viewpoint of achieving a balance between productivity and the size of the processing chamber 11.

Leg parts 116 and the placement parts 19 are provided in the processing chamber 11. The leg parts 116 extend from the bottom surface of the processing chamber 11 toward the Z-axis positive side. The plurality of leg parts 116 is disposed on the bottom surface at predetermined intervals. The plurality of placement parts 19 arranged at predetermined intervals along the Z axis is attached to the leg part 116. Each of the placement parts 19 is configured to support the tray 12 from below. Accordingly, the plurality of trays 12 is detachably supported by the plurality of placement parts 19. The detachable state refers to a state in which a mechanism for restraining the tray 12 does not exist in the placement parts 19 or a state in which a mechanism capable of switching as appropriate between the restraint state and the non-restraint state exists in the placement parts 19.

In the processing chamber 11, the plurality of trays 12 is arranged along the Z axis. According to such a configuration, the plurality of trays 12 can be disposed in a space-saving manner even for the processing chamber 11 having a small foot print. Accordingly, it is possible to efficiently manufacture the coated particles 93 while saving the space of the particle coating apparatus 1. The configuration of the leg parts 116 and the placement parts 19 is not limited to the illustrated configuration as long as the trays 12 can be supported in the configuration. Further, the number of the placement parts 19 is not particularly limited as long as it is plural, and is appropriately set according to, for example, the size of the processing chamber 11 and the size of the tray 12.

The material gas supply unit 142 and the oxidizing agent supply unit 144 are coupled to the processing chamber 11. The material gas supply unit 142 supplies the material gas G1 necessary for forming the coating film 92 into the processing chamber 11 and adjusts the partial pressure of the material gas G1 in the processing chamber 11. The material gas supply unit 142 includes, for example, a material gas reservoir, a pipe, a flow control valve, and so on. The oxidizing agent supply unit 144 supplies the oxidizing agent G2 necessary for forming the coating film 92 into the processing chamber 11 and adjusts the partial pressure of the oxidizing agent G2 in the processing chamber 11. The oxidizing agent supply unit 144 includes, for example, an oxidizing agent reservoir, a pipe, and a flow control valve. In FIG. 2, ozone O₃ is exemplified as the oxidizing agent G2. By using ozone as the oxidizing agent G2, it is possible to more efficiently form the coating film 92 which is denser and is uniform in film thickness. The material gas G1 and the oxidizing agent G2 are supplied together with a carrier gas containing an inert gas such as nitrogen gas or argon gas as a main component as necessary.

The processing chamber exhaust unit 15 exhausts the inside of the processing chamber 11. Accordingly, the inside of the processing chamber 11 can be depressurized. The processing chamber exhaust unit 15 includes, for example, a vacuum pump, a pressure gauge, a pipe, and an exhaust valve.

The processing chamber heating unit 16 heats the processing chamber 11 and accordingly heats the powder layer 90. Examples of the processing chamber heating unit 16 include a heater block, a film heater, a sheet heater, a seeds heater, and an infrared radiation heater. In FIG. 2, the processing chamber heating unit 16 is disposed outside the processing chamber 11, but the arrangement of the processing chamber heating unit 16 is not limited thereto. For example, the processing chamber heating unit 16 may be disposed inside the processing chamber 11 or may be incorporated in a wall body constituting the processing chamber 11. The processing chamber heating unit 16 may be provided as necessary, and may be omitted.

By providing such a processing chamber heating unit 16, the temperature of the powder layer 90 and the temperatures of the material gas G1 and the oxidizing agent G2 can be optimized. Accordingly, it is possible to more efficiently form the coating film 92 which is denser and is uniform in film thickness.

### 2. Treatment Target Powder and Treated Powder

Next, the treatment target powder and the treated powder will be described.

The coated particle 93 shown in FIG. 3 is one particle of the treated powder, and includes the particle 91 of the treatment target powder and the coating film 92.

The constituent material of the particles 91 (constituent material of the treatment target powder) is not particularly limited, and examples thereof include a metal material, a ceramic material, a glass material, a silicon material, a carbon material, and a resin material. The constituent material of the particles 91 may be a soft magnetic metal material. When the particles 91 made of the soft magnetic metal material 1 are used in a magnetic component such as an inductor, it is necessary to ensure insulation between the particles 91. By using the particle coating apparatus 1 described above, it is possible to form the coating film 92 having a sufficiently thin film thickness and a high coverage. As a result, the coated particles 93 capable of enhancing the magnetic characteristics and the insulation characteristics of the magnetic component are obtained. In addition, since the coating film 92 formed by the atomic layer deposition method is dense, for example, the coating film 92 contributes to the realization of the coated particle 93 having high insulating properties.

Examples of the soft magnetic metal material include, for example, pure iron, various Fe-based alloys such as an Fe—Si-based alloy such as silicon steel, an Fe—Ni-based alloy such as permalloy, an Fe—Co-based alloy such as permendur, an Fe—Si—Al-based alloy such as sendust, and an Fe—Cr—Si-based alloy, various Ni-based alloys, various Co-based alloys, and various amorphous alloys. Among these, examples of the amorphous alloys include Fe-based alloys such as Fe—Si—B-based, Fe—Si—B—C-based, Fe—Si—B—Cr—C-based, Fe—Si—Cr-based, Fe—B-based, Fe—P—C-based, Fe—Co—Si—B-based, Fe—Si—B—Nb-based, and Fe—Zr—B-based alloys, Ni-based alloys such as Ni—Si—B-based and Ni—P—B-based alloys, and Co-based alloys such as Co—Si—B-based alloys.

An average particle diameter D50 of the particles 91 is not particularly limited, but is preferably 0.1 μm or more and 50.0 μm or less, more preferably 0.5 μm or more and 10.0 μm or less, and still more preferably 1.0 μm or more and 3.5 μm or less. The average particle diameter D50 of the particles 91 can be obtained as a particle diameter when the cumulative amount from the smaller diameter side reaches 50% in a cumulative particle size distribution on a volume basis obtained by laser diffractometry.

### 3. Method of Coating Particles

Next, the method of coating the particles according to the embodiment will be described.

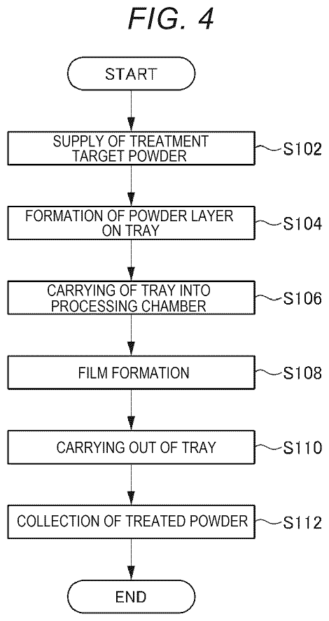

FIG. 4 is a process diagram illustrating the method of coating the particles according to the embodiment.

The method of coating the particles illustrated in FIG. 4 includes a treatment target powder supply step S102, a powder layer forming step S104, a tray carry-in step S106, a film forming step S108, a tray carry-out step S110, and a collection step S112. In the following description, a method using the above-described particle coating apparatus 1 will be described as an example, but the method of coating the particles according to the present disclosure may be a method using an apparatus other than the particle coating apparatus 1.

### 3.1. Treatment Target Powder Supply Step

In the treatment target powder supply step S102, the upper gate valve 136 shown in FIG. 1 is opened, and the treatment target powder is transferred from the supply hopper 22 into the anterior chamber 132. After a predetermined amount of the treatment target powder is transferred, the upper gate valve 136 is closed.

Thereafter, the inside of the anterior chamber 132 may be exhausted and depressurized as necessary. The pressure in the anterior chamber 132 is not particularly limited, but is preferably 10 kPa or less, and more preferably 1 kPa or less. Accordingly, it is possible to prevent oxygen and moisture from remaining in the anterior chamber 132, and it is possible to more reliably prevent oxidation, deterioration, and the like of the treatment target powder housed in the anterior chamber 132. The lower limit value of the pressure in the anterior chamber 132 may not be particularly set, but is preferably 1×10⁻⁵ Pa or more, and more preferably 1×10⁻³ Pa or more in consideration of an increase in cost for maintaining a reduced pressure state, a possibility that the effect due to the depressurization cannot sufficiently be obtained, and so on.

The treatment target powder housed in the anterior chamber 132 may be heated as necessary. A heating temperature of the treatment target powder is not particularly limited, and is preferably 30° C. or higher and 500° C. or lower, and more preferably 50° C. or higher and 300° C. or lower. Accordingly, sufficient preheating can be applied to the treatment target powder. As a result, the coating film 92 can be formed with a more uniform film thickness in the film forming step S108 described later.

Subsequently, the lower gate valve 137 is opened, and a predetermined amount of the treatment target powder out of the treatment target power housed in the anterior chamber 132 is supplied downward.

### 3.2. Powder Layer Forming Step

In the powder layer forming step S104, the tray 12 emptied is set in the powder layer forming unit 3 shown in FIG. 1. Then, while the tray 12 is moved by the tray conveyance unit 32, the treatment target powder (particles 91) supplied from the powder supply unit 13 is deposited on the tray 12. Subsequently, the deposited treatment target powder is leveled into a layer by the squeegee 30 shown in FIG. 1. Thus, the powder layer 90 shown in FIG. 1 is formed.

The method of forming the powder layer 90 is not limited to the above-described method. For example, the powder layer 90 may be formed by leveling the treatment target powder by applying vibration or the like.

Further, the powder layer 90 may be subjected to a pretreatment prior to the formation of the coating film 92 described later. Examples of the pretreatment include an ozone treatment, a radical treatment, an ultraviolet radiation treatment, a plasma treatment, a corona treatment, a drying treatment, and a solvent treatment. The pretreatment may be performed in the anterior chamber 132.

### 3.3. Tray Carry-In Step

In the tray carry-in step S106, first, the opening/closing unit 114 of the processing chamber 11 is opened. Then, the tray 12 holding the powder layer 90 is carried into the processing chamber 11 through the opening 113 in which the opening/closing unit 114 is opened. That is, the tray 12 is carried in through the opening/closing unit 114. By carrying the powder layer 90 together with the tray 12, an arrangement operation of the powder layer 90 can easily be performed compared to when the powder layer 90 is formed in the processing chamber 11. The tray 12 thus carried in is supported by the placement parts 19 shown in FIG. 2. Thus, the plurality of trays 12 are placed in a state of being arranged in the vertical direction. As a result, a number of trays 12 can be placed in the processing chamber 11 while avoiding an increase in size of the processing chamber 11.

### 3.4. Film Forming Step

In the film forming step S108, the coating film 92 is formed on the powder layer 90 in the processing chamber 11 by the atomic layer deposition method. The coating film 92 is formed, for example, as follows.

First, the opening/closing unit 114 is closed. Subsequently, the inside of the processing chamber 11 is exhausted and depressurized. The pressure in the processing chamber 11 before the introduction of the material gas G1 and the oxidizing agent G2 is not particularly limited, but is preferably 10 kPa or less, and more preferably 1 kPa or less. Accordingly, it is possible to prevent oxygen and moisture from remaining in the processing chamber 11. The lower limit value of the pressure in the processing chamber 11 may not be particularly set, but is preferably 1×10-5 Pa or more, and more preferably 1×10−3 Pa or more in consideration of an increase in cost for maintaining the reduced pressure state, a possibility that the effect due to the depressurization cannot sufficiently be obtained, and so on.

Subsequently, the treatment target powder housed in the processing chamber 11 is heated. This heating may be performed temporally overlapping the film formation of the coating film 92 described later, or may be performed separately from the film formation, that is, without temporally overlapping the film formation. The heating of the treatment target powder may be performed as necessary, and may be omitted. Furthermore, heating may be performed before the exhaust, or heating may be performed during the exhaust.

A heating temperature is not particularly limited, and is preferably 30° C. or more and 500° C. or less, and more preferably 50° C. or more and 300° C. or less. In particular, when the constituent material of the particles 91 is a material having low heat resistance such as a resin material, the heating temperature is preferably 30° C. or more and 150° C. or less, and more preferably 30° C. or more and 100° C. or less. The heating time at such a heating temperature is preferably 0.1 hour or more and 300 hours or less, more preferably 0.5 hour or more and 50 hours or less, still more preferably 1 hour or more and 40 hours or less.

Subsequently, the material gas G1 is introduced into the processing chamber 11 by the material gas supply unit 142. The material gas G1 thus introduced is adsorbed on the surfaces of the particles 91 of the treatment target powder. On this occasion, when the material gas G1 is adsorbed to the surfaces of the particles 91, the material gas G1 is less likely to be further adsorbed to other layers. Therefore, the film thickness of the coating film 92 finally obtained can be controlled with high accuracy. In addition, the material gas G1 also flows around and adsorbs to a portion that becomes a shadow or a gap. Accordingly, the thickness of the powder layer 90 shown in FIG. 1 is appropriately set according to the depth into which the material gas G1 can enter from the upper surface of the treatment target powder thus leveled.

The thickness of the powder layer 90 is, for example, preferably 1 mm or more and 50 mm or less, more preferably 3 mm or more and 30 mm or less, and still more preferably 5 mm or more and 20 mm or less.

Examples of the material gas G1 include a gas containing a precursor of the coating film 92. Specifically, for example, when the silicon oxide-based coating film 92 is formed, examples of the material gas G1 include dimethylamino silane, methylethylaminosilane, diethylamino silane, tris dimethylamino silane, bis diethylamino silane, and bis tertiary-butylaminosilane.

Examples of the constituent material of the coating film 92 to be formed include oxides such as hafnium oxide, tantalum oxide, titanium oxide, and chromium oxide, and nitrides such as aluminum nitride, titanium nitride, and tantalum nitride in addition to silicon oxide.

Subsequently, after the material gas G1 in the processing chamber 11 is discharged with the processing chamber exhaust unit 15, an inert gas such as nitrogen or argon is introduced as necessary. Thus, the material gas G1 is replaced. Introduction of the inert gas can be performed by the same method as that of introduction of the material gas G1 and the oxidizing agent G2, although not shown.

Subsequently, after the inert gas in the processing chamber 11 is discharged with the processing chamber exhaust unit 15, the oxidizing agent G2 is introduced into the processing chamber 11 with the oxidizing agent supply unit 144. Examples of the oxidizing agent G2 include plasma oxygen and water vapor in addition to ozone shown in FIG. 2.

The oxidizing agent G2 reacts with the material gas G1 adsorbed on the surfaces of the particles 91 of the treatment target powder, and forms the coating film 92. Similarly to the material gas G1, the oxidizing agent G2 also goes around to a portion to be shaded or a gap. Accordingly, the thickness of the powder layer 90 shown in FIG. 1 corresponds to the depth into which the oxidizing agent G2 can enter from the upper surface of the treatment target powder thus leveled.

Subsequently, after the oxidizing agent G2 in the processing chamber 11 is discharged with the processing chamber exhaust unit 15, an inert gas is introduced as necessary to replace the oxidizing agent G2. As described above, the coating film 92 is formed, and the coated particles 93 are obtained.

Note that, the introduction and the discharge of the material gas G1, and the introduction and the discharge of the oxidizing agent G2 may be repeated according to the target film thickness of the coating film 92. The film thickness can be increased according to the number of repetitions. Accordingly, a desired film thickness can easily be obtained.

Thereafter, the coated particles 93 may be subjected to a posttreatment as necessary. Examples of the posttreatment include a destaticizing treatment and a radical treatment.

Among them, the destaticizing treatment is a treatment for reducing the amount of electric charge due to charging of the coated particles 93. For example, an ionizer is used for the destaticizing treatment.

The film thickness of the coating film 92 is not particularly limited, but is, for example, preferably 1 nm or more and 500 nm or less, more preferably 2 nm or more and 300 nm or less, and still more preferably 4 nm or more and 200 nm or less. With such a film thickness, the film can be uniformly formed in a relatively short time. In addition, according to the atomic layer deposition method, the dense coating film 92 can be formed, and thus a sufficient insulation capability can be obtained even with such a thin film thickness. In this case, the coating film 92 having good insulation properties is obtained. The film thickness of the coating film 92 is an average value of measurement values obtained at five or more positions by observing a cross section of the coated particle 93 in an enlarged manner.

The formation of the coating film 92 as described above is performed in a state where the powder layer 90 is left stationary. Therefore, the coating film 92 having a uniform film thickness can be formed.

### 3.5. Tray Carry-Out Step

In the tray carry-out step S110, after the pressure in the processing chamber 11 is restored to the atmospheric pressure, the opening/closing unit 114 is opened. Then, the trays 12 on which the coated particles 93 are laid in a layer are carried out through the opening 113 in which the opening/closing unit 114 is opened. That is, the trays 12 are carried out through the opening/closing unit 114. By carrying out the coated particles 93 together with the trays 12, the carrying out operation of the coated particles 93 can easily be performed.

### 3.6. Collection Step

In the collection step S112, the treated powder (the coated particles 93) is collected from the trays 12.

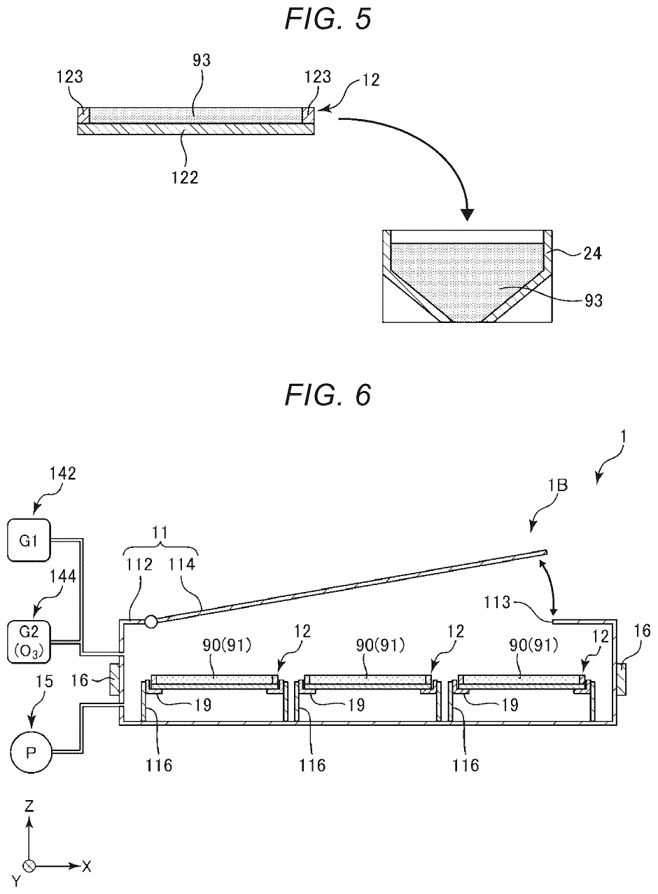

FIG. 5 is a diagram schematically illustrating a method of collecting the coated particles 93 from the tray 12 in the collection step S112.

Since the tray 12 is portable, the tray 12 may be tilted on the collection hopper 24 as shown in FIG. 5. This makes it possible to easily transfer the coated particles 93 laid on the tray 12 to the collection hopper 24.

In such a manner as described above, the treated powder can be collected.

### 4. Modified Examples

Next, the particle coating apparatus 1 according to modified examples of the embodiment described above will be described.

### 4.1. First Modified Example

FIG. 6 is a cross-sectional view illustrating the film forming unit 1B provided to the particle coating apparatus 1 according to a first modified example.

Hereinafter, the first modified example will be described, but in the following description, differences from the embodiment described above will be mainly described, and description of similar matters will be omitted.

The first modified example is the same as the embodiment described above except that the trays 12 in the processing chamber 11 are arranged in a different manner.

In the above-described embodiment, the placement parts 19 are configured such that the plurality of trays 12 are placed side by side in the vertical direction in the processing chamber 11. In contrast, the placement parts 19 shown in FIG. 6 are configured such that the trays 12 are placed side by side in the horizontal direction. According to such a configuration, it is possible to reduce the height of the processing chamber 11. Accordingly, it is possible to realize the particle coating apparatus 1 excellent in workability in carrying in and out the trays 12. In addition, since the trays 12 do not overlap each other when viewed from the thickness direction (Z-axis direction) of the powder layer 90, it is easy to uniformly ensure an opportunity of contact between the material gas G1 or the oxidizing agent G2 and the treatment target powder. Therefore, the coating film 92 can be formed with a more uniform film thickness.

In the above described first modified example, substantially the same advantages as those of the above described embodiment may be obtained.

### 4.2. Second Modified Example

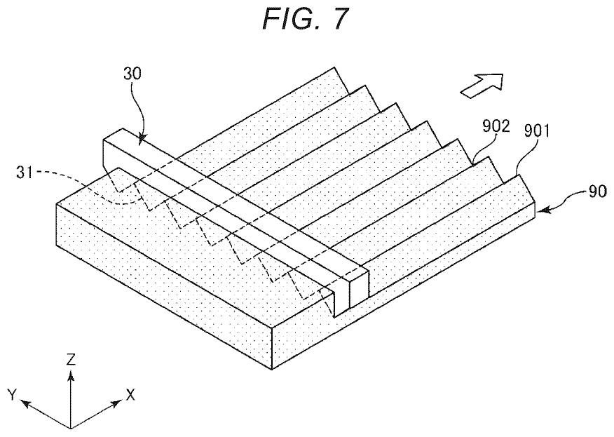

FIG. 7 is a perspective view illustrating the squeegee 30 provided to the particle coating apparatus 1 according to a second modified example.

Hereinafter, the second modified example will be described, but in the following description, differences from the above-described embodiment will mainly be described, and description of similar matters will be omitted.

The second modified example is substantially the same as the above-described embodiment except that the shape of the squeegee 30 is different.

The squeegee 30 shown in FIG. 7 has a plate shape extending along the Y axis. The upper surface of the treatment target powder along the X-Y plane is formed while leveling the treatment target powder by passing the treatment target powder along the X axis below the squeegee. As a result, the powder layer 90 having this upper surface is obtained.

The squeegee 30 illustrated in FIG. 7 has a ridge line 31. The shape of the ridge line 31 is reflected on the upper surface of the powder layer 90. The ridge line 31 shown in FIG. 7 has a corrugated shape. Therefore, the upper surface of the powder layer 90 formed by the squeegee 30 is formed into a corrugated shape as shown in FIG. 7. Specifically, as a result of leveling the upper surface of the powder layer 90 shown in FIG. 7 by the squeegee 30, the upper surface of the powder layer 90 has a shape including the convex lines 901 or the grooves 902 extending along the X axis.

By using the squeegee 30 having the ridge line 31 corrugated in such a manner, it is possible to further increase the surface area of the upper surface of the powder layer 90 compared to when using, for example, a squeegee having a linear ridge line. Accordingly, when the coating film 92 is formed in the powder layer 90, the material gas G1 and the oxidizing agent G2 can be made to penetrate deeper. As a result, it is possible to increase the amount of the treated powder that can be manufactured at a time, and increase the manufacturing speed of the treated powder.

The shape of the ridge line 31 is not limited to the corrugated shape shown in FIG. 7, and the ridge line 31 may sufficiently be configured such that the shape of the ridge line 31 left on the upper surface of the powder layer 90 by the squeegee 30 includes the convex lines 901 or the grooves 902. That is, it is sufficient for the ridge line not to be a straight line, but has a shape including some convex portion or concave portion. However, in view of the easiness in homogenizing the penetration amount of the material gas G1 or the oxidizing agent G2, it is preferable that the shape is configured in a repetitive pattern as shown in FIG. 7. The powder layer 90 may sufficiently include the convex lines 901 or the grooves 902, but preferably includes both of them from the viewpoint of increasing the surface area.

In the above described second modified example, substantially the same advantages as those of the above described embodiment may be obtained.

### 4.3. Third Modified Example

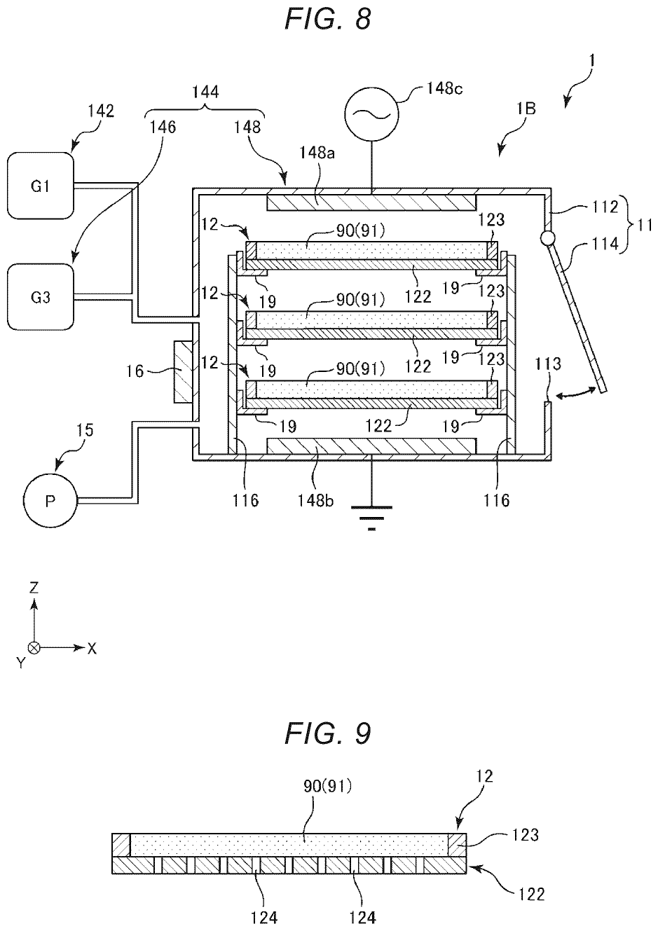

FIG. 8 is a cross-sectional view illustrating the film forming unit 1B provided to the particle coating apparatus 1 according to a third modified example.

Hereinafter, the third modified example will be described, but in the following description, differences from the embodiment described above will mainly be described, and description of similar matters will be omitted.

The third modified example is the same as the embodiment except that the oxidizing agent supply unit 144 includes an oxygen gas supply unit 146 and a plasma generating unit 148 shown in FIG. 8.

The oxygen gas supply unit 146 supplies the oxygen gas G3 necessary for generating plasma oxygen into the processing chamber 11, and adjusts the partial pressure of the oxygen gas G3 in the processing chamber 11. The oxygen gas supply unit 146 includes, for example, an oxygen gas reservoir, a pipe, and a flow control valve.

The plasma generating unit 148 includes an upper electrode 148a, a lower electrode 148b, and a high frequency power supply 148c. The upper electrode 148a is disposed at the upper portion of the processing chamber 11 and is coupled to the high frequency power supply 148c. The lower electrode 148b is disposed in a lower part of the processing chamber 11 and is grounded.

The oxygen gas G3 is supplied into the processing chamber 11 by the oxygen gas supply unit 146, and in this state, the oxygen gas G3 is changed into plasma oxygen by the plasma generating unit 148. That is, plasma oxygen is generated in the processing chamber 11. Accordingly, plasma oxygen generated in the processing chamber 11 can be used as the oxidizing agent G2. By using plasma oxygen as the oxidizing agent G2, the heating temperature when forming the coating film 92 can be lowered. That is, a film can be formed at a lower temperature. Accordingly, even when the constituent material of the particles 91 has low heat resistance, the coating film 92 can be formed.

The high frequency power supply 148c may be coupled to the lower electrode 148b and the upper electrode 148a may be grounded.

Further, the upper electrode 148a and the lower electrode 148b may be coupled to the high frequency power supply 148c so as to have respective polarities opposite to each other. In this case, the generated plasma oxygen can be drawn toward the lower electrode 148b side. As a result, the plasma oxygen as the oxidizing agent G2 can penetrate deeper into the powder layer 90. As a result, it is possible to increase the amount of the treated powder that can be manufactured at a time, and increase the manufacturing efficiency of the treated powder.

In the above described third modified example, substantially the same advantages as those of the above described embodiment may be obtained.

### 4.4. Fourth Modified Example

FIG. 9 is a cross-sectional view illustrating a tray 12 provided to the particle coating apparatus 1 according to a fourth modified example.

Hereinafter, the fourth modified example will be described, but in the following description, differences from the embodiment described above will mainly be described, and description of similar matters will be omitted.

The fourth modified example is substantially the same as the embodiment described above except that the configuration of the tray 12 is different.

The tray 12 shown in FIG. 9 includes the bottom plate 122 having a plurality of through holes 124, and the frame body 123 disposed on one surface of the bottom plate 122. The through holes 124 penetrate the bottom plate 122. Therefore, when the tray 12 holds the powder layer 90, the material gas G1 and the oxidizing agent G2 can permeate not only from above but also from below the powder layer 90. As a result, it is possible to increase the amount of the treated powder that can be manufactured at a time, and increase the manufacturing speed of the treated powder.

Examples of the bottom plate 122 having the through holes 124 include a mesh, a punched metal, a fabric, and a porous material. For example, in the case of a mesh or cloth, the opening corresponds to the through hole 124. In the case of a porous material, the communication hole provided therein corresponds to the through hole 124.

The inner diameter of the through hole 124 is appropriately set according to the outer diameter of the particle 91 of the treatment target powder, and may be equal to or larger than the outer diameter, but is preferably smaller than the outer diameter.

In the above described fourth modified example, substantially the same advantages as those of the above described embodiment may be obtained.

### 5. Advantages Exerted by Embodiment or Modified Examples

As described above, the particle coating apparatus 1 according to the embodiment or the modified examples is an apparatus for forming the coating film 92 on the surface of the particles 91 of the treatment target powder by the atomic layer deposition method, and includes the processing chamber 11, the material gas supply unit 142, the oxidizing agent supply unit 144, the processing chamber exhaust unit 15, the plurality of trays 12, and the placement parts 19. The processing chamber 11 includes the chamber 112 and the opening/closing unit 114 that opens and closes the chamber 112. The material gas supply unit 142 supplies the material gas G1 into the processing chamber 11. The oxidizing agent supply unit 144 supplies the oxidizing agent G2 into the processing chamber 11. The processing chamber exhaust unit 15 exhausts the inside of the processing chamber 11. The plurality of trays 12 can be carried into the processing chamber 11 through the opening/closing unit 114, and hold the powder layer 90 in which the treatment target powder is laid in a layer. The placement parts 19 are disposed in the processing chamber 11, and the plurality of trays 12 is placed thereon in a detachable state.

According to such a configuration, since the powder layer 90 is used for forming the coating film 92 in a state where the powder layer 90 is left at rest, the coating film 92 can be formed with a uniform film thickness. Further, since the opening/closing unit 114 capable of carrying the tray 12 holding the powder layer 90 into the processing chamber 11 is provided, the powder layer 90 can be formed outside the processing chamber 11, and as a result, the production efficiency of the coated particles 93 can be improved. Further, since the processing chamber 11 includes the placement parts 19 on which the plurality of trays 12 can be placed, a large amount of the treatment target powder can be supplied in one film formation step. Therefore, according to the above-described configuration, the particle coating apparatus 1 capable of efficiently manufacturing the particles 91 coated with the thin coating film 92 having a uniform film thickness, that is, the coated particles 93 can be obtained.

The placement parts 19 may be configured such that the plurality of trays 12 is placed side by side in the vertical direction.

According to such a configuration, the plurality of trays 12 can be disposed in a space-saving manner even for the processing chamber 11 having a small foot print. Accordingly, the coated particles 93 can more efficiently be manufactured.

The placement parts 19 may be configured such that the plurality of trays 12 is placed side by side in the horizontal direction.

According to such a configuration, it is possible to reduce the height of the processing chamber 11. Accordingly, it is possible to realize the particle coating apparatus 1 excellent in workability in carrying in and out the trays 12. In addition, since the trays 12 do not overlap each other, it is easy to uniformly ensure an opportunity of contact between the material gas G1 or the oxidizing agent G2 and the treatment target powder. Therefore, the coating film 92 can be formed with a more uniform film thickness.

The particle coating apparatus 1 may include the powder supply unit 13 and the powder layer forming unit 3. The powder supply unit 13 is disposed outside the processing chamber 11, accommodates the treatment target powder, and supplies a predetermined amount of the treatment target powder. The powder layer forming unit 3 is disposed outside the processing chamber 11, and deposits the treatment target powder supplied from the powder supply unit 13 on the tray 12 to form the powder layer 90.

According to such a configuration, since the powder layer forming unit 3 is disposed outside the processing chamber 11, the powder layer 90 can be formed without being restricted by space or workability. Therefore, it is possible to easily speed up the formation of the powder layer 90.

The powder layer forming unit 3 may include the squeegee 30. The squeegee 30 levels the treatment target powder deposited on the tray 12. The squeegee 30 has the ridge line 31 that comes into contact with the treatment target powder when leveling the treatment target powder. The ridge line 31 is configured such that the shape of the ridge line 31 left on the surface of the treatment target powder leveled by the squeegee 30 includes the convex lines 901 or the grooves 902.

According to such a configuration, it is possible to further increase the surface area of the upper surface of the powder layer 90 compared to when a squeegee having a linear ridge line is used. Accordingly, when the coating film 92 is formed in the powder layer 90, the material gas G1 and the oxidizing agent G2 can be made to penetrate deeper. As a result, it is possible to increase the amount of the treated powder that can be manufactured at a time, and increase the manufacturing speed of the treated powder.

The oxidizing agent G2 may be ozone. In this case, the particle coating apparatus 1 may further include the processing chamber heating unit 16. The processing chamber heating unit 16 heats the powder layer 90.

According to such a configuration, it is possible to more efficiently form the coating film 92 which is denser and has a uniform film thickness.

The oxidizing agent G2 may be plasma oxygen. In this case, the oxidizing agent supply unit 144 may include the oxygen gas supply unit 146 and the plasma generating unit 148. The oxygen gas supply unit 146 supplies the oxygen gas G3 into the processing chamber 11. The plasma generating unit 148 converts the oxygen gas G3 into plasma oxygen.

According to such a configuration, plasma oxygen thus generated can be used as the oxidizing agent G2, and the heating temperature at the time of forming the coating film 92 can be lowered accordingly. That is, a film can be formed at a lower temperature. Accordingly, even when the constituent material of the particles 91 has low heat resistance, the coating film 92 can be formed.

The tray 12 may include the bottom plate 122 having the through holes 124 and the frame body 123 disposed on one surface of the bottom plate 122.

According to such a configuration, when the tray 12 holds the powder layer 90, the material gas G1 and the oxidizing agent G2 can permeate not only from above but also from below the powder layer 90. As a result, it is possible to increase the amount of the treated powder that can be manufactured at a time, and increase the manufacturing speed of the treated powder.

In addition, the method of coating the particles according to the embodiment or the modified examples is a method of forming the coating film 92 on the surface of the particles 91 of the treatment target powder by the atomic layer deposition method, and includes the tray carry-in step S106, the film forming step S108, and the tray carry-out step S110. In the tray carry-in step S106, the plurality of trays 12 holding the powder layer 90 formed by laying the treatment target powder in a layer form are carried into the processing chamber 11 through the opening/closing unit 114. In the film forming step S108, after the opening/closing unit 114 is closed, the coating film 92 is formed in the powder layer 90 in the processing chamber 11 by the atomic layer deposition method. In the tray carry-out step S110, the opening/closing unit 114 is opened, and the plurality of trays 12 holding the powder layer 90 in which the coating film 92 is formed are carried out from the processing chamber 11.

According to such a configuration, since the powder layer 90 is used for forming the coating film 92 in a state where the powder layer 90 is left at rest, the coating film 92 can be formed with a uniform film thickness.

The treatment target powder may be formed of a soft magnetic metal material. Further, the coating film 92 may be formed of an insulating material.

According to such a configuration, it is possible to form the coating film 92 having a sufficiently thin film thickness and a high density and coverage, and thus it is possible to obtain the coated particles 93 capable of realizing a magnetic component having excellent magnetic characteristics and insulating characteristics.

Although the particle coating apparatus and the method of coating the particles according to the present disclosure have been described above based on the illustrated embodiment, the present disclosure is not limited thereto.

For example, the particle coating apparatus according to the present disclosure may be what is obtained by replacing each unit of the embodiment described above with any component having the same function, or what is obtained by adding any constituent to the embodiment described above. In addition, the method of coating the particles according to the present disclosure may be what is obtained by adding a step having any purpose to the embodiment described above.

What is claimed is:

1. A particle coating apparatus configured to form a coating film on a surface of a particle of a treatment target powder using an atomic layer deposition method, comprising:
a processing chamber including a chamber, and an opening/closing unit configured to open and close the chamber;
a material gas supply unit configured to supply a material gas into the processing chamber;
an oxidizing agent supply unit configured to supply an oxidizing agent into the processing chamber;
a processing chamber exhaust unit configured to exhaust the processing chamber;
a plurality of trays which is configured to be carried into the processing chamber through the opening/closing unit, and which is configured to hold a powder layer formed of the treatment target powder laid in a layer; and
a placement part which is disposed in the processing chamber, and on which the plurality of trays is detachably placed.

2. The particle coating apparatus according to claim 1, wherein
the placement part is configured such that a plurality of trays is placed side by side in a vertical direction.

3. The particle coating apparatus according to claim 1, wherein
the placement part is configured such that a plurality of trays is placed side by side in a horizontal direction.

4. The particle coating apparatus according to claim 1, further comprising:
a powder supply unit which is disposed outside the processing chamber, which is configured to accommodate the treatment target powder, and which is configured to supply a predetermined amount of the treatment target powder; and
a powder layer forming unit which is disposed outside the processing chamber, which is configured to deposit the treatment target powder supplied from the powder supply unit on the tray, and which is configured to form the powder layer.

5. The particle coating apparatus according to claim 4, wherein
the powder layer forming unit includes a squeegee configured to level the treatment target powder deposited on the tray,
the squeegee has a ridge line which is configured to come into contact with the treatment target powder when leveling the treatment target powder, and
the ridge line is configured such that a shape of the ridge line left on a surface of the treatment target powder leveled by the squeegee has a shape including a convex line or a groove.

6. The particle coating apparatus according to claim 1, further comprising:
a processing chamber heating unit configured to heat the powder layer, wherein
the oxidizing agent is ozone.

7. The particle coating apparatus according to claim 1, wherein
the oxidizing agent is plasma oxygen, and
the oxidizing agent supply unit includes
an oxygen gas supply unit which is configured to supply oxygen gas into the processing chamber, and
a plasma generating unit which is configured to convert the oxygen gas into the plasma oxygen.

8. The particle coating apparatus according to claim 1, wherein
the tray includes a bottom plate having a through hole and a frame body disposed on one surface of the bottom plate.

9. A method of coating a particle for forming a coating film on a surface of a particle of a treatment target powder using an atomic layer deposition method, comprising:
carrying a plurality of trays holding a powder layer formed by laying the treatment target powder in a layer into a processing chamber through an opening/closing unit;
forming the coating film in the powder layer using the atomic layer deposition method in the processing chamber after the opening/closing unit is closed; and
opening the opening/closing unit to carry the plurality of trays holding the powder layer coated with the coating film out from the processing chamber.

10. The method of coating the particle according to claim 9, wherein
the treatment target powder is made of a soft magnetic metal material, and
the coating film is made of an insulating material.
